(19) United States
(12) Patent Application Publication
(10) Pub. No.: US 2026/0110719 A1
(43) Pub. Date: Apr. 23, 2026

(54) CONTINUOUS ON - LINE INSULATION MEASUREMENT SYSTEM FOR INSULATED OR FLOATING NEUTRAL ELECTRICAL CIRCUITS

(71) Applicant: TERO SOLUTIONS SAS, Bogota D.C. (CO)

(72) Inventor: Natalia Parra VELASQUEZ, Bogota D.C. (CO)

(21) Appl. No.: 19/256,359

(22) Filed: Jul. 1, 2025

(30) Foreign Application Priority Data
Oct. 17, 2024 (CO) NC2024/0014120

(51) Int. Cl. G01R 27/02; G01R 19/25; G01R 31/34

(52) U.S. Cl. CPC G01R 27/025; G01R 19/2506; G01R 31/343

(57) ABSTRACT

A continuous on-line insulation measurement system for insulated or floating neutral electrical circuits reduces pumping equipment installation times and allows for the measurement and recording of insulation values, phase-to-phase resistance of the electrical system, and measurement of data from the bottom sensor, if applicable. Thus, for any data outside the installation parameters, the system can generate an alarm so that operators can resolve the problem. Once the pumping equipment is installed and ready for operation, the system can operate online by adding a neutral choke or reactor, and take insulation and bottom sensor measurements, record them, and alert of any problems, even while the pumping equipment is operating. This makes predicting a fault more direct by monitoring the insulation trend.

### TECHNICAL FIELD

This disclosure relates to the technique of measuring electrical integrity variables applied to any three-phase system with a floating neutral for insulation measurement, or alternatively, a three-phase system with or without ground reference for phase-to-phase resistance measurement. Specifically, this technique is applied in the installation of an electrically submersible pumping system where a three-phase motor is placed on the bottom, a power cable feeds it, and permanent monitoring of these electrical or physical integrity variables is required.

### BACKGROUND OF THE INVENTION

Traditional electrically submersible pumping (ESP), ESPCP, or similar equipment is generally installed in a similar manner. Specifically, one or more three-phase motors are used, which are energized by a Motor Lead Extension (MLE) to a power cable, to provide the necessary power for the system to operate. The motor normally provides the mechanical power to drive a centrifugal, progressive cavity pump (PCP), or similar pump, which moves the fluid from the bottom to the surface. During the installation of the motor and cable, it is necessary to periodically check the insulation condition along with other parameters such as phase-to-phase resistance, pressure, and temperature. This insulation is measured by measuring the phase to ground, allowing for the integrity value to be obtained because the electrical system is not grounded. If a bottom sensor is used, the insulation measurement is reversed, placing the positive lead to ground and the negative lead to the phase, since the sensor has an internal blocking diode that allows for a representative insulation value to be obtained. In particular, insulation is measured using a megger, which provides a DC voltage ranging from 250V to 5000V, with 1000V occasionally used when a bottom sensor is available.

Additionally, for phase-to-phase resistance measurements, a multimeter or milliohmmeter is used to measure the resistance between each of the three phases. These values are small depending on the equipment installed, but since they are typically star shaped, they have a representative and expected value of between 5 and 15 ohms. However, regardless of whether the connection is star or delta, the three values taken must be the same, as any difference could represent a fault in the electrical system or an imbalance. Insulation measurements typically decrease as the equipment goes deeper into the ground because the temperature to which the motors and cables are subjected increases; however, they must always reach the expected value according to the motor or cable manufacturer. On the other hand, phase-to-phase resistance must be the same for all three, but increases in value as the equipment goes deeper into the ground. Pressure, temperature, vibration, and leakage current variables are readings that must be taken by the downhole sensor using a Readout surface device. This device communicates with the downhole sensor using a proprietary protocol. The latter is connected to the motor's star center, continuously transmitting the aforementioned variables. Once the equipment has reached the bottom of the well, all surface equipment is connected, typically a step-up transformer, a variable frequency drive or soft starter or switchboard, and a vent box, which is responsible for eliminating gases that may migrate from the well and prevent them from reaching other equipment. If a downhole sensor is available, a unit must be installed to generate a virtual neutral or star center on the surface using three high-inductance coils connected in a star. This three-phase coil (choke) is the interface with the downhole sensor. The three phases are connected directly to the high-voltage circuit after the step-up transformer, while the choke's star center is connected to the Readout sensor reading unit. At this point in the choke, any applied voltage will appear directly at the motor's star center because common-mode voltage is being applied. The applied voltage can be either AC or DC. In the case of the Readout, a DC voltage is typically applied, which, when applied at the motor's star center, powers the sensor. This voltage will consume a current that, depending on its shape and protocol, will be read by the Readout, sending data on pressure, temperature, vibration, leakage current, and other variables.

According to the above, continuous online insulation measurement systems can be found in the state of the art, such as those disclosed in documents CN214585810 and CN215219016.

Document CN214585810 discloses an online insulation measurement system that enables the electrical insulation measurement of multiple devices using a single measurement device. Specifically, said system is characterized by including a controller, a detection device, a power supply device, and more than one detection unit. The detection device is connected to a measurement bus, and its signal output is connected to the controller, while the power supply device is connected to the power input end of the detection device. Each detection unit comprises a DC contactor and a device to be detected. The power input end of the device to be detected is connected to the AC bus, the DC contactor is connected to the device to be detected, its output end is connected to the measurement bus, and its control end is connected directly or indirectly to the controller.

On its part, document CN215219016 discloses a line and phase selection device for insulation faults in low-voltage distribution systems for offshore oil and gas fields. Specifically, the device is characterized by including an online insulation monitoring device, a network communication device, and a line and phase selection device for faults. The online insulation monitoring device includes a monitoring diagnostic circuit, an audiovisual alarm, a current signal generator for positioning, and a display device. The monitoring diagnostic circuit is respectively connected to the audiovisual alarm device, the current signal generator for positioning, the display device, and a transformer within the low-voltage distribution system. This circuit is used to monitor the insulation resistance between phases and ground within the low-voltage distribution system. Likewise, said monitoring diagnostic circuit includes an injection signal source and a sampling resistor. The injection signal source is used to inject signals into the low-voltage distribution system, and the sampling resistor is used to collect insulation resistance values between phases and ground within the low-voltage distribution system. The current signal generator for positioning is connected to the transformer and the low-voltage bus within the low-voltage distribution system, and is also connected to the display device and at least one line and phase fault selection device via the network communication device. Each line and phase fault selection device is connected to corresponding loads through three-phase conductors within the low-voltage distribution system.

However, the traditional systems mentioned in the previous documents have several disadvantages. For example, it is not possible to measure pressure, temperature, vibrations, and leakage current simultaneously, as they require three different instruments, which cannot coexist. These measurements are performed manually every few meters as the equipment is lowered. Consequently, many hours pass between measurements, and there is uncertainty about the integrity of the equipment during this time when nothing is being measured. Additionally, when a decision is made to take measurements, all operations must be stopped and these measurements performed, generating unproductive time ranging from several minutes to hours. Likewise, in prior art or current systems, it is not possible to collect electrical integrity data, that is, it is not possible to measure system insulation or phase-to-phase resistance values. In fact, the only relevant data available is the leakage current delivered by the sensor, which provides an indication that the system's insulation is failing. Typically, before obtaining a worrisome leakage current reading, sensors lose communication, and the well eventually declares itself with a phase to ground. However, there is no way to predict this gradual decline since sensor communication is quite fragile.

In accordance with all of the above, the invention presented in this document demonstrates a practical solution both at the time of pumping system installation and during its operation, and it is also continuous.

### BRIEF DESCRIPTION

The continuous insulation measurement system (1) may comprise one or more sensor measurement or readout circuits (1-d); or the sensor measurement or readout circuit (1-d) may not be part of the invention, so that the continuous insulation measurement system (1) communicates with it and obtains the data necessary to execute its functions. Specifically, communication between the continuous insulation measurement system (1) and the sensor measurement or readout circuit (1-d) is carried out through a serial communication port, either RS232, RS485, among others, using a Modbus protocol. The continuous measurement system (1) queries the sensor measurement or readout circuit (1-d) in slave mode for the values of interest through this port. The latter responds to all information queries at the discretion of the master, as required by said communication protocol.

In another embodiment, a continuous measurement circuit for de-energized equipment operation (IRH) (2) comprising the continuous insulation measurement system (1), one or more mounting frames (2-a), one or more high-voltage connection conductors (2-b), one or more wireless interfaces (2-c), one or more audible alarms (2-d), one or more light alarms (2-e), one or more touchscreen displays or HMIs (2-f), one or more external box control circuits and wireless communication ports (2-g), and one or more protective boxes or chassis for the measurement system (2-h).

In another embodiment, a continuous measurement circuit for energized equipment operation (IMO) (3) comprising the continuous insulation measurement system (1), one or more switches (1-i), the wireless interface (2-c), the choke unit or neutral reactor (3-a), the star center of the choke (3-b) and a star center of the step-up transformer (3-c).

### BRIEF DESCRIPTION OF THE FIGURES

FIG. 1. It schematically illustrates the interior of the IRH measurement system and its constituent blocks. In particular, the high voltage switch or multiplexer (1-a), the megger (megado) or insulation measurement circuit (1-b), the phase-to-phase resistance measurement circuit (1-c), the sensor measurement circuit or Readout (1-d), the voltage presence measurement circuit (1-e), the power supply and battery system (1-f), the power supply and charging circuit (1-g), the control circuit (1-h) and the switch (1-i) are evident.

FIG. 2. This schematically illustrates the human-machine interface with the IRH measurement system. Particularly evident are the audible alarm (2-d), the light alarm (2-e), the touch screen display or HMI (2-f), and the external box control circuit and wireless communication ports (2-g).

FIG. 3. Illustrates the IMO component diagram for use in a permanent installation in a pumping system. It shows the three-wire diagram of the pumping system and how the IMO connects to it. Specifically, the continuous insulation measurement system (1), the high-voltage switch or multiplexer (1-a), the wireless interface of the IRM or IMO (2-c), the continuous measurement circuit for operation of energized equipment (IMO) (3), the choke unit or neutral reactor (3-a), the choke star center (3-b), the step-up transformer star center (3-c), the power cable (4), the pothead or motor plug (6), the downhole motor (7), the downhole sensor (10), the vent box (11), the step-up transformer (12), the frequency converter, switchboard or soft starter (15), and the sensor blocking diode (16) are evident.

FIG. 4. Physically illustrates both a surface and downhole installation of a pumping system and the location of the IMO. Specifically, the continuous measurement circuit for the operation of energized equipment (IMO) (3), the power cable (4), the pothead or plug to the motor (6), the bottom motor (7), the production tubing (9), the bottom sensor (10), the vent box (11), the step-up transformer (12), the wellhead (13), the frequency converter, switchboard or soft starter (15), and the cable reel or spooler (19) are evident.

FIG. 5. Physically illustrates an IRH installation along with its human-machine interface on a cable spooler in use during the installation of the pumping system. The IRH is mounted inside the spooler and rotates with it, while the human-machine interface optionally is mounted outside. The human-machine interface can also be a mobile phone or tablet. Specifically, the mounting frame (2-a), high-voltage connection conductors (2-b), the wireless interface of the IRM or IMO (2-c), the audible alarm (2-d), the light alarm (2-e), the touch screen display or HMI (2-f), the protective box or chassis for the continuous measurement system (2-h), the continuous measurement circuit for operation of energized equipment (IMO) (3), the power cable (4), and the cable termination (8) are evident.

FIG. 6. Illustrates the measurement scheme during installation using conventional instruments versus how an automated IRH measurement system would be used, simplifying tasks during pumping system installation. Specifically, the sensor measurement circuit or Readout (1-d), the continuous measurement circuit for de-energized equipment operation (IRH) (2), the power cable (4), the sheave to facilitate cable installation in the well (5), the pothead or motor plug (6), the downhole motor (7), the cable termination (8), the downhole sensor (10), the wellhead (13), the well (14), the Megger (17), the multimeter (18), the cable reel or spooler (19), and the ESP pump (20) are evident.

FIG. 7. Illustrates the single-line system of the pumping system during its installation with the IRH connected on the far right. In particular, the continuous measurement circuit for de-energized equipment operation (IRH) (2), the power cable (4), and the downhole motor (7) are evident. The equivalent resistances displayed by the instrument when using the system's megohmmeter are shown in the lower diagram. Specifically, the continuous measurement circuit for de-energized equipment operation (IRH) (2) will be those of the power cable (IRc) and the motor (IRm) in parallel.

FIG. 8. Illustrates the single-line system of the pumping system during its energized operation, with the IMO connected in the middle. Specifically, the continuous measurement circuit for energized equipment operation (IMO) (3), the choke unit or neutral reactor (3-a), the power cable (4), the downhole motor (7), and the step-up transformer (12) are shown. The equivalent resistances displayed by the instrument when using the system's megohmmeter are shown in the lower diagram. Specifically, the continuous measurement circuit for energized equipment operation (IMO) (3) with IRM, IRC, IRCH, and IRTX

### DETAILED DESCRIPTION

The present invention relates to a continuous insulation measurement system (1) that allows in an automated and sequential manner to take: (i) insulation measurements of the three-phase electrical system with floating neutral, whether with said system de-energized or energized, the latter achieved by means of other external accessories that generate an additional floating neutral such as the choke; (ii) measurement of the resistance existing between phases of the measured electrical system, by means of the system to be measured, de-energized; (iii) taking a reading from a background sensor (10), which may or may not be external to this invention, and if it were installed in the electrical system to be measured, this can be carried out with the system to be measured energized or de-energized. For sensor readings, it is important that the system of this invention communicates with a Readout board, which may or may not be included in the present invention. This board interprets the reading data through a communication port or analog signals. However, this invention must connect and disconnect the power and data signals that the readout needs to have in the electrical measurement system. Furthermore, this system allows for a permanent voltage or current detection system for safety purposes, allowing for monitoring the regular operation of the system and also for the detection and appearance of unexpected voltages or currents in the electrical system. These are the result of regeneration that the system to be measured may present under certain conditions. For example, during the installation of a de-energized system, it may experience unexpected electrical generation due to environmental issues at the location where it is installed. Thus, this function warns that the system presents spontaneous energy generated by the system to be measured.

For the purposes of the present invention, a de-energized continuous isolation measurement system refers to the mode in which the pumping equipment is in the installation process, that is, the pumping equipment is being assembled and driven into the well. During this operation, electrical and physical parameters must be measured, which are recorded by the continuous measurement circuit for de-energized equipment operation (IRH) (2).

For the purposes of the present invention, an energized continuous isolation measurement system refers to the mode in which the pumping equipment has already been installed, that is, the pumping equipment is already at the bottom of the well, and the entire surface installation is connected and energized. Therefore, the downhole equipment is operating, pumping hydrocarbons or other fluids to the surface. During this operation, electrical and physical parameters must be measured, which are recorded by the continuous measurement circuit for energized equipment operation (IMO) (3).

For the purposes of the present invention, the functions performed by the continuous insulation measurement system (1) are activated sequentially, requiring a direct connection to the electrical system to be measured.

The system (1) allows for the taking and recording of insulation and phase-to-phase resistance values of the electrical system, and for measuring data from the bottom sensor, if applicable. Thus, any data outside the installation parameters of the invention generates an alarm so that operators can resolve the problem. Once the pumping equipment is installed and ready for operation, the invention can operate online by adding a choke or neutral reactor, taking insulation and bottom sensor measurements, recording them, and alerting of any problems even while the pumping equipment is operating. This makes predicting a fault more direct by monitoring the insulation trend.

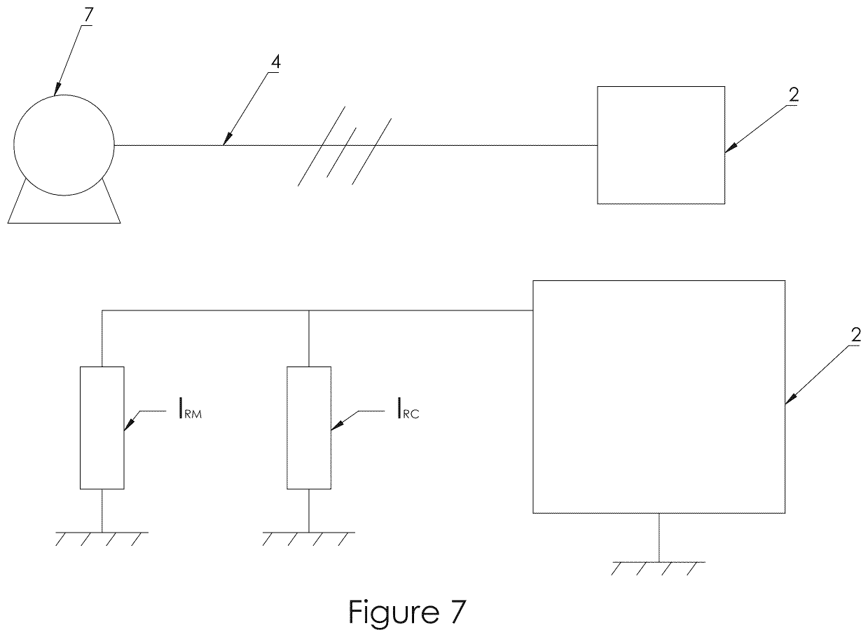

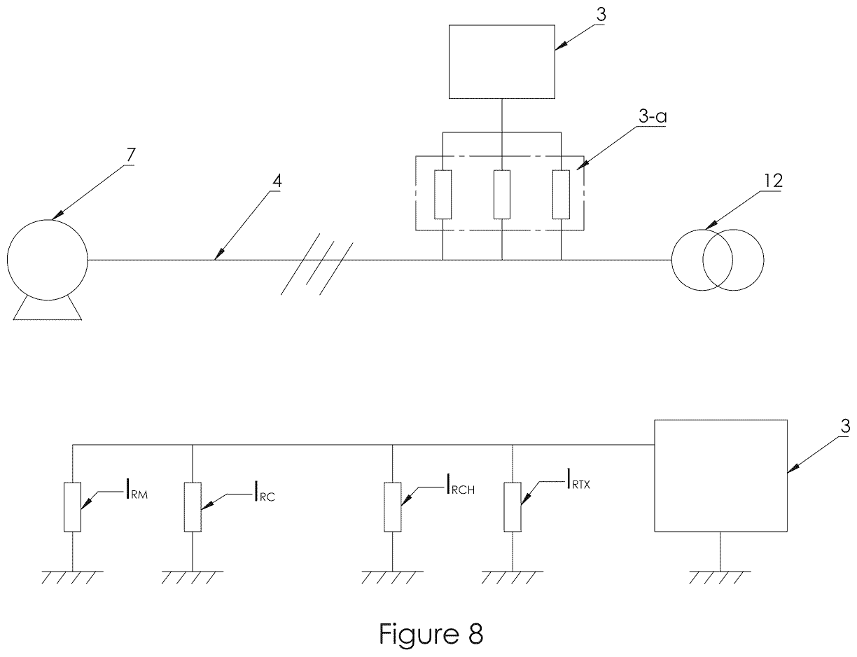

For the purposes of the present invention, the electrical system to be measured refers to the circuit in which electrical measurements such as insulation and phase-to-phase resistance will be taken. These measurements should be within certain parameters to ensure their integrity. This electrical circuit differs depending on whether it is being installed or already installed. In the case of installation, the electrical circuit to be measured is essentially composed of a three-phase system consisting of: one or more power cables (4), one or more potheads or plugs to the motor (6) and one or more motors of the pumping equipment (7), as shown in FIG. 7. In the event that the equipment is already installed and operating energized, the electrical system to be measured is composed of the aforementioned in the background and, in addition, on the surface it includes one or more step-up transformers (12) and one or more choke units or neutral reactors (3-a), as shown in FIG. 8.

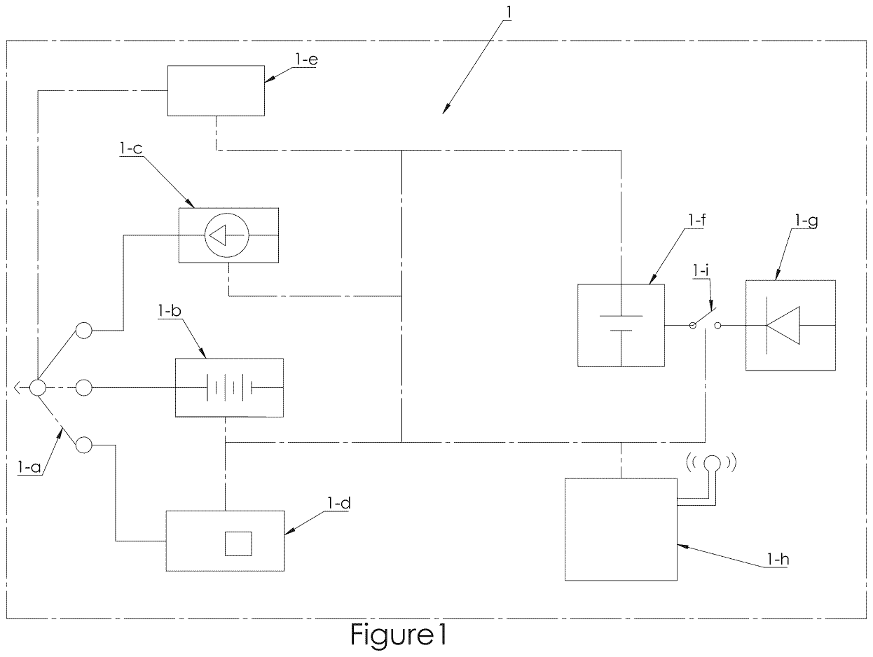

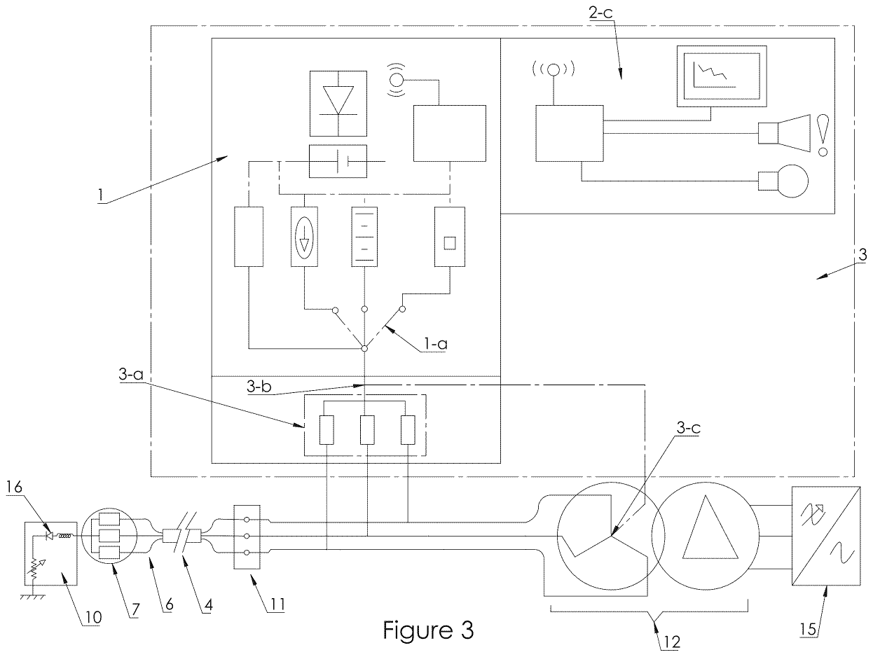

For the purposes of the present invention, the continuous insulation measurement system (1), as shown in FIGS. 1 and 3, comprises one or more high-voltage switches or multiplexers (1-a), one or more insulation measurement or measuring circuits (1-b), one or more phase-to-phase resistance measurement circuits (1-c), one or more voltage presence measurement circuits (1-e), one or more power and battery systems (1-f), one or more power and charging circuits (1-g), one or more control circuits (1-h), and one or more switches (1-i).

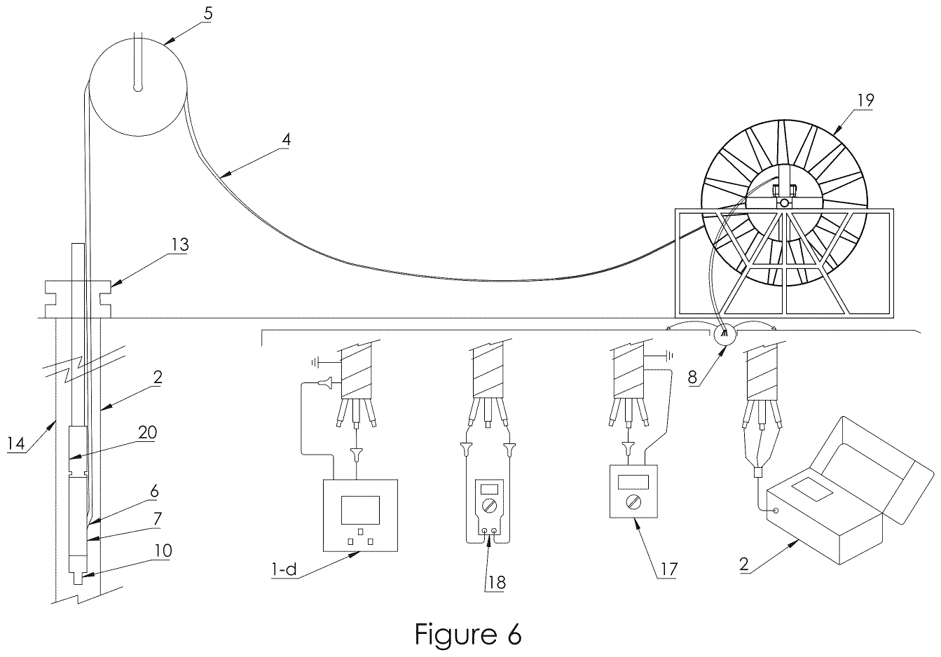

Additionally, as shown in FIGS. 1 and 6, the continuous insulation measurement system (1) may comprise one or more sensor or readout measurement circuits (1-d); The sensor measurement circuit or readout (1-d) may not be part of the invention, so the continuous insulation measurement system (1) communicates with it and obtains the necessary data to execute its functions. Thus, the continuous insulation measurement system (1) links all the functionalities used simultaneously and managed by this device.

For the purposes of the present invention, the high-voltage switch or multiplexer (1-a), as seen in FIGS. 1 and 3, refers to a device used to alter the direction of the electrical current in a circuit or to divert it to a different circuit. Specifically, the high-voltage switch or multiplexer allows for sequential electrical connection to the three-phase system to be measured, ensuring proper electrical disconnection. Particularly, the high-voltage switch or multiplexer (1-a) has a high insulation value when the contacts are in the open position and low resistance when the contacts are closed. This switch has one or more common points that will go directly to the electrical system to be measured. Thus, the switch (1-a) is selected from dry-contact relays and solid-state switches.

For the purposes of the present invention, a dry-contact relay refers to an electromagnetic device controlled by an electrical circuit that does not require an electrical connection between the control circuit and the circuit being controlled.

For the purposes of the present invention, a solid-state switch refers to a device that allows one or more points to be connected electrically without the need for movable contacts. Instead, it uses an array of different types of transistors that, when activated, electrically connect the input and output without moving parts. These come in various types, voltages, currents, and closing speeds.

For the purposes of the present invention, the insulation measurement or megger circuit (1-b), as shown in FIG. 1, is a high-value DC voltage generator. Specifically, the megger or insulation measurement circuit (1-b) consists of a voltage boost source and can deliver voltages ranging from 100 Vdc to 5000 Vdc. Preferably, the megger circuit (1-b) can deliver voltages ranging from 500 Vdc to 4500 Vdc, 1000 Vdc to 4000 Vdc, 1500 Vdc to 3500 Vdc, and 2000 Vdc to 3000 Vdc. Preferably, voltages of 1000 Vdc are used to ensure proper insulation measurement without damaging any component of the electrical system being measured. This 1000 Vdc source is floating and has no ground reference, so its positive or negative output terminals can be applied interchangeably to the electrical system being measured.

For the purposes of the present invention, the phase-to-phase resistance measuring circuit (1-c), as seen in FIG. 1, is a differential measuring circuit that allows either a precise voltage or current to be injected at a point, where it enters at one point and returns at the other end. If a precise and known voltage is applied, the resulting current must be measured accurately at those two differential points. If a precise and known constant current is applied, the voltage generated by said current when passing through the resistance to be measured must be measured. This forms a circuit called a milli-ohmmeter. Both the values of the constant source (constant voltage or current) and its result to be measured (current or voltage respectively) are captured by a high-resolution analog-to-digital converter. The resistance result will be the quotient of said values following the Ohm's law formula.

For the purposes of this invention, a high-resolution analog-to-digital converter refers to a circuit capable of receiving electrical signals of different values, typically within a defined voltage range, originating from an amplifier or signal adapter in a measurement circuit, sensor, etc. This converter circuit converts said analog magnitude into a digital representation for processing by a microprocessor. Typically, this digital magnitude can be represented with a low-resolution value, such as 8 bits (256 possible values), or within high resolution, which would be 16 bits (65,536 possible values), or 24 bits or more (1,677,7216 possible values or more).

For the purposes of the present invention, the sensor measurement circuit or readout (1-d), as seen in FIGS. 1 and 6, is typically mounted within the continuous insulation measurement system, as it must be controlled not only in its readings but also in its output so that the applied voltages do not interfere with the other circuits of this invention. The readouts deliver a direct current voltage of approximately 100 to 150 Vdc, or in some cases, a direct current of 9 to 10 mA, which must be switched to avoid interfering with the other functions. The switch (1-a) is responsible for opening its output and ensuring that there are no applied voltage crosstalk or additional impedance resulting from the readout that could affect the readings of the other instruments. Specifically, the continuous insulation measurement system (1) provides its interface to the sensor measurement circuit or readout (1-d) and groups the quantities that the latter measures in the system simultaneously.

For the purposes of the present invention, the voltage presence measurement circuit (1-e), as shown in FIG. 1, has a permanent connection at the common point of the switch (1-a). It consists of a high-impedance voltage meter that detects any voltage presence at the connection points, where the impedance value must be known so as not to affect the measurement reading of the circuit (1-b).

For the purposes of the present invention, the power supply and battery system (1-f), as shown in FIG. 1, supplies each of the aforementioned circuits with all the voltages necessary for independent operation. This power supply system (1-f) has a battery that can be lithium, acid, among others, and with sufficient ampere-hours to operate the system continuously without the need for external power for as long as convenient, from minutes to several hours depending on the application. Specifically, lithium, acid, capacitive, or any other type of battery that can supply the ampere-hours necessary to operate this equipment for the required time. The battery allows the entire measurement circuit to be completely isolated, especially when operating with the metering circuit (1-b), since it must be completely isolated from ground during this process.

For the purposes of the present invention, the switch (1-i), as seen in FIG. 1, refers to an element within the circuit that allows or denies the flow of current in an electrical circuit. In particular, it ensures that the circuit is isolated from ground by opening it, since it disconnects the battery from any power or load point formed by the power and load circuit (1-g).

For the purposes of the present invention, the power and load circuit (1-g), as seen in FIG. 1, refers to a source that draws power from the grid and allows a battery to be safely charged while simultaneously powering the rest of the circuit. Specifically, this circuit is composed of an isolated switching-type input source with a variable voltage range to withstand grid variations and a DC output voltage for powering the circuits and charging the battery.

For the purposes of the present invention, the control circuit (1-h), as seen in FIG. 1, is a microprocessor circuit that has several communication ports, analog and digital inputs and analog digital outputs, which allow to coordinate and interpret the operation of each of the circuits (1-b), (1-c), (1-d) and (1-e). Particularly, the control circuit (1-h) positions the switch (1-a) where appropriate according to the measurement to be taken and activates each of the circuits (1-b), (1-c), (1-d) and (1-e). This takes the corresponding readings, whether of megohm, phase-to-phase resistance, or physical data from the background sensor (10) and records them in a memory. Also, the control circuit (1-h) is responsible for acting and generating alarms in the event that the voltage presence measurement circuit (1-e) has detected a high voltage or current in the system to be measured. All collected values are stored in an internal memory with a time record for later graphing. This control circuit (1-h) also has a set of programmable alarms for each of the measured variables, especially for low insulation, phase-to-phase resistance imbalance or differences with the expected. Redundant alarms can also be programmed for the values delivered by the background sensor (10) (pressure, temperatures, vibrations, etc.).

For the purposes of the present invention, the set of alarms refers to the values that, due to their high or low value, are considered of interest for the user to stop the operation and review the values and trends in order to make decisions. A low isolation value would imply that the pumping equipment has been damaged during installation and likely requires removal from the well for repair. The alarms are selected from a group comprising isolation-related alarms (high and low), phase-to-phase resistance alarms (high and low, and unbalance), alarms for the presence of voltage in the grid, and alarms for downhole sensor data (high, low, disconnection).

Optionally, the control circuit (1-h) may include a human-machine interface (HMI) for interaction and setting of all variables and alarms. Additionally, it has a wireless communications port that can communicate with either a cell phone application or another external interface, depending on the application, including a SCADA. This communication can be via Wi-Fi, Bluetooth, or any other optical or radio wireless protocol that allows information to be transmitted back and forth to peripherals.

Specifically, the switch (1-a) has one or more common points that go directly to the electrical system to be measured. For measuring voltage and sensor readings, only one common point is required, since this signal is normally connected to an external star center generated by a choke if the equipment is energized, or to any of the phases of the system to be measured if the circuit is de-energized. For phase-to-phase resistance measurements, the common point of the switch (1-a) does require three points, since this phase-to-phase measurement requires connection to all three phases of the system to be measured. A signal is applied to one phase and returned through another, measuring differentially. The permanent measurement of generated voltage or current is the only function that is permanently activated and does not switch, as it is connected to the common point of the switch (1-a). At the other end of the switch, the different measurement circuits are connected, allowing for independent results for each measurement.

Particularly for applications with downhole sensors, it is necessary to place the negative terminal on the switch (1-a) and the positive terminal is connected to the ground of the system being measured. In this way, a voltage of −1000 Vdc (negative voltage) would be applied to the system being measured. The megger or insulation measurement circuit (1-b) additionally has a high-precision shunt-type current measurement system that allows determining the current drained when the aforementioned voltage is applied. Both voltage and current are measured using a high-resolution analog-to-digital converter (ADC) and will be used to determine the system's insulation resistance by applying Ohm's law. This source is activated by the control board (1-h), which will also be responsible for processing the voltage and current data.

Specifically, the constant voltage or current sources that make up the milli-ohmmeter circuit are activated by the control system (1-h), which will also be responsible for recording the measured values.

Additionally, the voltage presence measurement circuit (1-e) can also operate using the current measurement mode using a current transformer in cases where the leads of the element to be measured are short-circuited, in the case of an induction motor (IM) or a permanent magnet motor (PMM).

For the purposes of the present invention, an induction motor (IM) refers to a machine that transforms the electrical energy supplied to it into mechanical energy, specifically rotational energy. Induction motors can be either three-phase or single-phase, and they can be asynchronous or synchronous.

For the purposes of the present invention, a permanent magnet motor (PMM) refers to three-phase motors whose rotor does not have a squirrel cage like induction motors, but instead has magnets. These in particular generate high voltage when their axis is rotated manually or by some external force.

In the event that the presence of voltage is being measured, the voltage presence measurement circuit (1-e) can discern that it is in the presence of voltage applied by the same instrument, for example, the 1000 Vdc megulation by the insulation measurement or megulation circuit (1-b), or the voltage applied for the phase-to-phase resistance measurement of the phase-to-phase resistance measurement circuit (1-c), or the voltage applied by the Readout (1-d). All of these voltages are known by the instrument and should not be considered an alarm. However, if there is any background regenerative voltage, especially when using permanent magnet motors, these are usually of great magnitude greater than 1000V and in alternating current. And they are considered critical from the point of view of personal safety. In the presence of these voltages, the circuit issues an interruption command that is detected by the control circuit (1-h), activating a visual and audible alarm. In this way, operators working in the well will know that a regenerative situation exists and must take the relevant precautions. In the event that this continuous isolation measurement system (1) is working permanently during well operation, this circuit additionally detects a system imbalance, either because the three-phase system to be measured has a phase to ground or because a choke fuse (3-a) has opened.

In one embodiment, this continuous insulation measurement system (1) defined above can be used as a continuous measurement circuit for operation of de-energized equipment or IRH (Insulation running in Hole) (2) which would be during the installation of the electrosubmersible equipment in the well. Particularly, in this embodiment, as shown in FIGS. 6 and 7, the system comprises one or more high voltage switches or multiplexers (1-a), one or more insulation measuring or measuring circuits (1-b), one or more phase-to-phase resistance measuring circuits (1-c), it is connected to one or more sensor or Readout measuring circuits (1-d), in addition, it also comprises one or more voltage presence measuring circuits (1-e), one or more power and battery systems (1-f), one or more power and charging circuits (1-g), one or more control circuits (1-h), one or more switches (1-i), one or more mounting racks (2-a), one or more high voltage connection conductors (2-b), one or more wireless interfaces (2-c), one or more audible alarms (2-d) one or more light alarms (2-e), one or more displays or touch HMI (2-f), one or more external box control circuits and wireless communications ports (2-g) and one or more protective boxes or chassis for the measurement system (2-h).

For the purposes of the present invention, the continuous measurement circuit for de-energized equipment operation (IRH) (2) requires a runtime of several hours, which may be more than 12 hours.

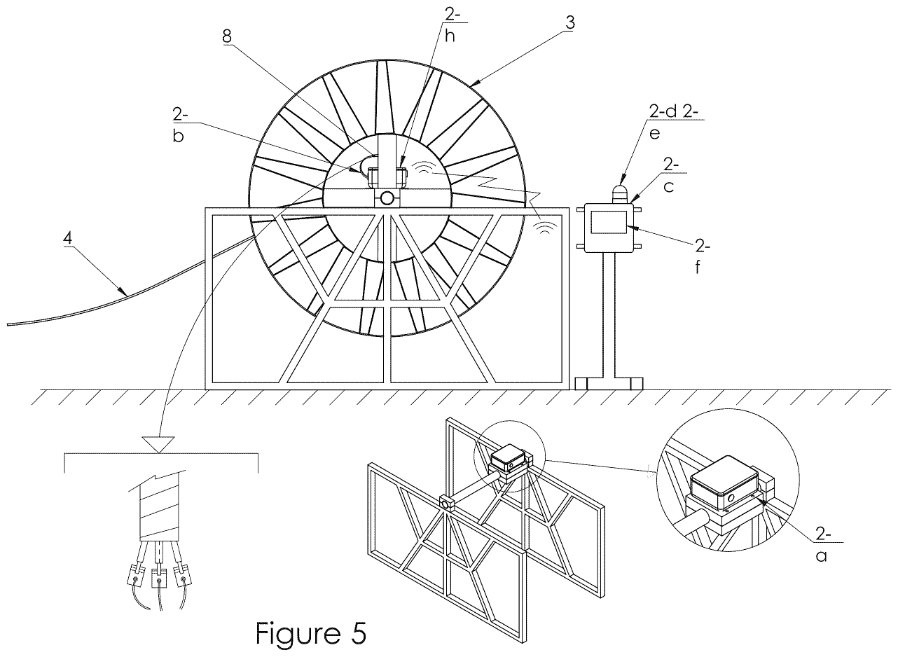

For the purposes of the present invention, the mounting frames (2-a), as seen in FIG. 5, refer to a metal structure that can hold the IRH and its accessories and simultaneously anchor to the spooler or reel (19), either on its shaft or on its sides. This is such that when the spooler or reel rotates, the entire IRH structure can also rotate safely without coming loose. Specifically, the mounting frames (2-a) may be comprised of a metal sheet to which the IRH circuit and accessories are bolted, and in turn, a clamp for securing it to the shaft. These are mechanically fastened using bolts.

Specifically, a pole frame refers to a metal or plastic mount that can support the electronics box, either the IMO alone or the wireless interface (2-c). This mount holds all of these devices and can be mounted on a pole. This pole can be bolted to the floor, ensuring the boxes are at an ergonomically acceptable height for a user.

Specifically, a spooler-type frame refers to the structure on which the IRH is mounted to secure the device within the drum on the reel. This allows the instrument to rotate with the spooler when the pumping equipment is installed.

Preferably, the frame is selected from the pole, spooler, or cable reel type.

For the purposes of the present invention, the high-voltage connection conductors (2-b), as shown in FIG. 5, refer to the conductors exiting the IRH and allowing a direct connection to the power cable at its three conductor terminals at its cable termination (8). An additional cable exiting the IRH will be connected to the armor or ground of the power cable (4). This connection is normally made with a 16 AWG or larger gauge cable with insulation made of either PVC, EPDM, Teflon, or Silicone, and capable of resisting high voltages exceeding 5000V. The connection between the power cable and the high-voltage connection conductors is made using clamps or clamps to prevent them from coming loose when the spooler (19) is rotating during operation.

For the purposes of the present invention, the wireless interface (2-c), as shown in FIGS. 3 and 5, refers to a device that enables wireless communication with the IRH and simultaneously displays values or alarms on a touch screen. This device can be fixed, as shown in the figure, or it can be a tablet or mobile phone that communicates with the IRH through a specific application or website to obtain the measured information.

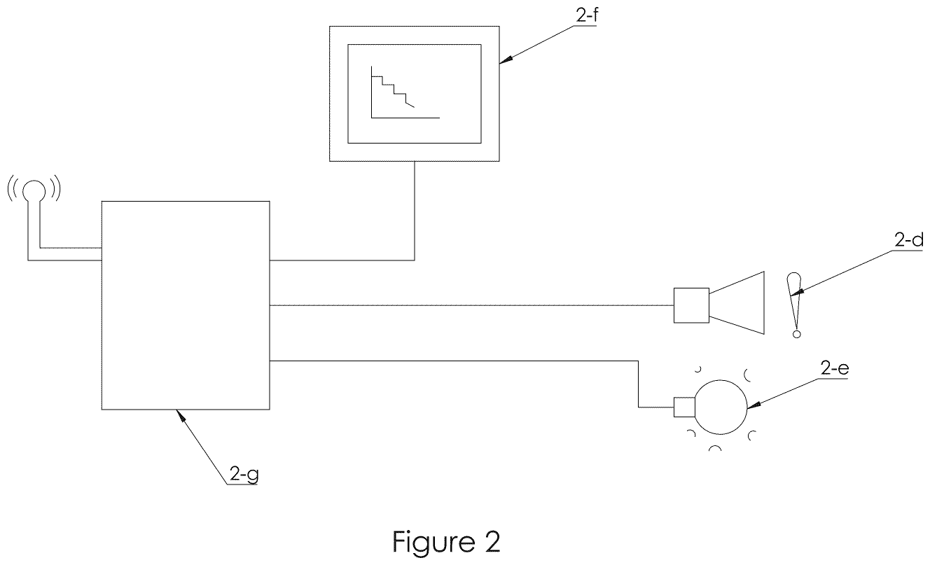

For the purposes of the present invention, the audible alarms (2-d), as shown in FIGS. 2 and 5, refer to an accessory to the wireless device that allows an audible sound to be emitted at the location when any of the IRH alarms are activated, in cases of low insulation, phase imbalance, loss of communication data, among others, and that require the attention of the field operator. This device is mounted on the wireless interface (2-c). It could also be an audible alarm emitted by a tablet or mobile phone connected to the IRH.

For the purposes of the present invention, light alarms (2-e), as shown in FIGS. 2 and 5, refer to an accessory of the wireless device that allows a visible light to be emitted at the location when any of the IRH alarms is activated, in cases of low insulation, phase imbalance, loss of communication data, among others, and that requires the attention of the field operator. This device is mounted on the wireless interface (2-c). It could also be a visual alarm emitted by a Tablet or mobile phone that is connected to the IRH.

For the purposes of the present invention, the touchscreen displays or HMI (2-f), as shown in FIGS. 2 and 5, are the interface through which the user can view process values. This interface is located within the wireless interface (2-c). It also allows for alarm and configuration adjustments through user interaction. The touchscreen has its own backlight and can be used with any of the current technologies, such as resistive, surface capacitive, projected capacitive, surface acoustic wave, and infrared. In the case of using a tablet or mobile device, it would correspond to their display.

For the purposes of the present invention, the external box control circuits and wireless communication ports (2-g), as shown in FIG. 2, correspond to a microprocessor-based electronic controller with memory and various types of communication ports. These include various wireless ports such as Wi-Fi, Bluetooth, Zigbee, and others to generate a communication link with the IRH. This module also has memory to record the process read with a time stamp.

For the purposes of this invention, the protective enclosures or chassis for the measurement system (2-h), as shown in FIG. 5, are a sealed enclosure that protects all the internal electronics comprising the IRH. The enclosure must be made of a durable, metallic, or plastic material that can withstand continuous field operating conditions. Typically, it has a NEMA 3R or higher protection rating.

The high-voltage cables required to take readings in the system emerge from the protective enclosure. These cables typically consist of three conductors, and a high-voltage return cable, typically made of silver-or tin-plated copper or aluminum with insulation greater than 5000V (2-b). This IRH enclosure communicates wirelessly via the aforementioned port (1-g) with another external enclosure (2-c) to view the entire process, IRH trends, and configure alarms, etc. This external box has one or more wireless ports that enter the control system (2-g) with a microprocessor to interact with port (1-g). It has one or more touch-screen displays (2-f) for improved interaction. When an alarm occurs, it can be displayed and heard through the audible and visual sirens (2-d) and (2-e), respectively.

For the purposes of the present invention, the entire interface system (2-f) can also be a cell phone application if the hardware is to be simplified.

In another embodiment, this continuous insulation measurement system (1) defined above can be used as a continuous measurement circuit for the operation of energized equipment (IMO) (3), which would correspond to the operation of the submersible power equipment already installed in the well and put into production. Particularly, in this embodiment, as evidenced in FIGS. 3, 4, 5 and 8, the system comprises one or more high voltage switches or multiplexers (1-a), one or more insulation measuring or measuring circuits (1-b), one or more phase-to-phase resistance measuring circuits (1-c), it is connected to one or more sensor or readout measuring circuits (1-d), in addition, it also comprises one or more voltage presence measuring circuits (1-e), one or more power and battery systems (1-f), one or more power and charging circuits (1-g), one or more control circuits (1-h), one or more switches (1-i), the wireless interface (2-c), the choke unit or neutral reactor (3-a), the choke star center (3-b) and a step-up transformer star center (3-c).

For the purposes of the present invention, the continuous measurement circuit for energized equipment operation (IMO) (3) requires an autonomy of minutes or more while the meg is in process.

For the purposes of the present invention, the choke unit or neutral reactor (3-a), as seen in FIGS. 3 and 8, refers to a neutral reactor, essentially three inductors with very high Henry values, on the order of 100 to 300 Henry. At one end, these are connected to the network to be measured, and at the other end, the three are short-circuited, forming a star configuration. In this way, a virtual neutral is reconstructed to which the IMO (3) can be connected for insulation measurement. The three coils, having high inductance, will also present a very high impedance, and there will be practically no currents circulating through them.

For the purposes of the present invention, the star center of the choke (3-b), as shown in FIG. 3, refers to the physical connection of the three inductors within the choke. These three high-inductance, and therefore high-impedance, coils must be connected in a star configuration. That is, these three short-circuited terminals form what is known as a star center. At the other end, the inductors are normally connected to the phases of a three-phase system. In this way, the star center of the choke forms a virtual neutral where the three-phase power signals cancel each other out.

For the purposes of the present invention, the star center of the step-up transformer (3-c), as shown in FIG. 3, refers to the short-circuit connection point of the three secondary coils of the step-up transformer. At this point, a virtual neutral will also exist where the three-phase power signals cancel each other out. This point is electrically equivalent to the star center of the choke.

Specifically, the star center of the choke (3-b) is connected to the output of the continuous measurement system (1), specifically at the common point of the commutator (1-a). Alternatively, the output of the continuous measurement system (1) can be connected to the star center of a step-up transformer (12) if this is available at the star center of the step-up transformer (3-c), thus simplifying the IMO hardware (3). The three choke terminals are connected to the network to be measured either at the terminals of the step-up transformer (12) or at the vent box (11).

For the purposes of the present invention, the modalities that are evident in the present invention are divided into two main modalities, the first corresponds to the installation of the ESP pumping equipment (20) that corresponds to the IRH (2), as evidenced in FIGS. 6 and 7, and the second corresponds to the operation with the pumping equipment energized and producing hydrocarbons or any fluid from a well (14) or cistern to the surface or elevation that corresponds to the IMO (3), as evidenced in FIGS. 3, 4, 5 and 8.

Particularly, FIG. 2 shows that it is possible to have a display or human-machine interface that connects wirelessly outside the spooler to view the progress of the variables or review the cause of the alarm (2-f), where the interface can be a cell phone or tablet with an application.

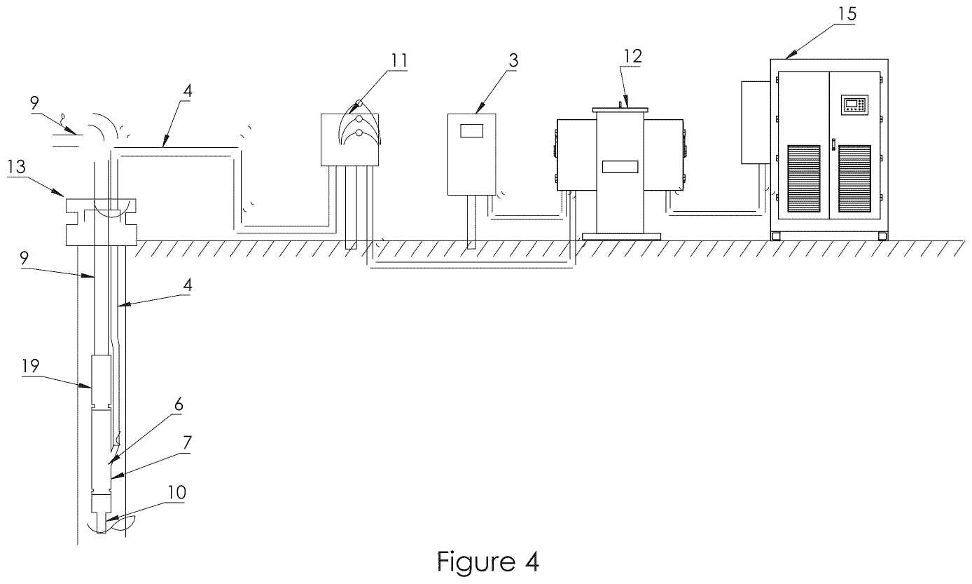

FIGS. 3 and 4 show that once the equipment is up and running, the IMO (3) which essentially uses the same hardware as the IRH (2) and the interface (2-c), is connected to the star center of the Choke (3-b) or neutral of the transformer (3-c). With a series of switches (1-a) that allows the Readout connection (1-d) to be opened and a megger (1-b) to be applied which will be in reverse, that is, positive to ground and negative to the star center. In this way, a DC or AC voltage of known value is applied and the current in microamperes is measured to determine the insulation resistance (1-b), as shown in FIGS. 1 and 3.

In FIG. 5 it can be seen that the IMO (2) placed inside the cable Spooler (19) and rotated with it so as not to interfere mechanically, where it is possible to configure alarms in case the insulation falls below a certain value, or that the phase to phase resistances are not equal and fall below a certain value or any sensor data is out of a range or simply that communication is lost with the background sensor (10). All alarms and variables can be displayed by a device embedded in the box (2) or externally connected wirelessly (2-c), using audible (2-d) and visual (2-e) alarms. Trends and values can be displayed through the man-machine interface (2-f). The IRH (2) and this interface (2-f) communicate wirelessly via the wireless modules (1-h) and (2-g), as shown in FIGS. 1 and 2. It is important to note that the invention has a series of contacts (1-a) that allow the Readout measurement circuit (1-d) to be opened and either the insulation measurement circuit (1-b) or the phase-to-phase resistance measurement circuit (1-c) to be connected.

Specifically, FIG. 6 shows that during installation, the equipment integrity measurement operation must be stopped and three different instruments manually used, which cannot coexist or measure simultaneously: a Megger (17), a multimeter or milliohmmeter (18), and a Readout (1-d). The IRH invention (2) allows the first two instruments (Megger and milliohmmeter) to be combined into a single device and a communications port for the Readout (1-d). In this way, an autonomous power supply system (1-f) and (1-g) in FIG. 1 allows all measurements to be taken sequentially and automatically. Thus, a datalogger record is created that records all measurements with the time of occurrence. This records the actual system insulation from kOhms to GigaOhms, phase-to-phase resistances in milliohms to ohms for all three phases, and all sensor data. The unit, which has a control and recording system (1-h), is installed in a box with a rechargeable battery (1-f) and (1-g) and allows all the aforementioned hardware to be powered, including the readout (1-d).

FIG. 6 also shows another option: powering the IRH reading equipment (2) directly from an external source using slip rings. This allows the spooler (19) to rotate freely and not interfere with any power cables, preventing it from becoming tangled. Although the preferred option is for the equipment to be autonomous and battery-powered (1-f), the insulation values measured by the IRH will be those of the power cable (IRc) and the motor (IRm) in parallel, as shown in FIG. 7.

In the case of the IMO (3), the insulation value measured will be the parallel insulation of the power cable (IRc), the background motor (IRm), the secondary of the step-up transformer (IRtx), and the choke (IRch). It is possible to obtain the average values of the transformer and choke to calculate the background values of interest (power cable and motor), as shown in FIG. 8.

Both the IMO (3) and the IRH (2) allow the recording of values and their trends, allowing for the determination of polarization, electrical absorption, and other parameters of interest that allow determining the integrity of the electrical system, as well as predicting faults based on trends.

### EXAMPLES

The application with the continuous measurement circuit for operation of de-energized equipment (IRH) (2) began by trying to simplify field tasks that require a lot of installation time. Initially, a system with a sensor reading only from the bottom sensor was used. The equipment was mounted on the spooler (19) and was fed by friction discs so that when the cable spooler (19) rotated, it had appropriate power for its operation. An audible alarm (2-d) was set to detect any drop in the variables. For insulation, it is only possible to use a parameter called “current leakage.” This task allowed detecting any problem during the run, but it also required stopping the maneuver every certain number of installed pipes and measuring insulation values, phase by phase, with manual instruments. Essentially, the time saved was if a sensor loss appeared between measurements, but it did not substantially reduce the equipment installation time. Subsequently, a battery (1-f) was added so that the readout (1-d) mounted on the spooler (19) has electrical autonomy and does not have to place the slip rings. This is what is generally installed for the so-called continuous monitoring. On the contrary, in the IRH (2) of the invention, the necessary instruments were added to have a continuous measurement of the additional parameters such as megado and the phase-to-phase resistance. First, the megado was tested in which it was determined that in order to function in practice it is necessary to ensure a correct disconnection of the readout (1-d) and not have sums of voltage sources and that generate potential faults. Several automatic switches (1-a) were tested until achieving one that allows taking measurements from the bottom sensor (1-d), completely discharge the cable (4) and then make a megado measurement, without the switching accessories affecting the value of the measurement. Finally, by providing a reliable switch (1-a), the phase-to-phase measurements were added using the milli-ohmmeter circuit. The coordination system initially generated problems because the cable remained charged after a megohm, destroying the phase-to-phase resistance measurement circuit (1-c). To this end, the coordination and protection of the circuit were improved so that this charging phenomenon, due to capacitance in the cable, does not damage the instrument. Sensor measurement operations, megohm (1-b), phase-to-phase (1-c), and voltage detection (1-a) are now powered by a single battery (1-f), which simplifies installation. Alarms (2-d) and/or (2-e) can be programmed with any of the variables measured. This considerably reduces installation times and allows operators assembling electrosubmersible equipment to concentrate solely on that task, thus improving installation reliability.

In the continuous measurement circuit for energized equipment operation (IMO) (3), no similar system existed until now. This utilizes all the benefits of the IRH (2) except for phase-to-phase measurement. The initial tests were conducted using a choke system, where a manual megger was applied directly with the downhole equipment running. Consistent measurements were taken. Subsequently, the entire megger circuit, which is now shared by the IRH (2) and IMO (3), was developed. A subsequent step was to coordinate the operation of the downhole sensor with insulation measurement using the choke normally used for sensor readings, which has proven to work well in the laboratory.

The continuous measurement circuit for de-energized equipment operation (IHR) (2) and the continuous measurement circuit for energized equipment operation (IMO) (3) are capable of connecting and disconnecting the sensor measurement circuit, or Readout (1-d), to sequence other types of measurements, such as electrical system insulation or phase-to-phase resistance. Likewise, (2) and (3) allow the device to combine and coordinate insulation measurement by applying DC or AC voltage as appropriate through an internal source and current measurement. A DC source can be applied to each phase of the system to measure phase-to-phase resistance, and finally one or more communication ports to take a readout reading (1-d). IHR and IMO are capable of recording all the variables indicated above with the time of occurrence and displaying them on a human-machine interface through values, graphs, and trends over time. They also display whether any alarms occurred and their cause. Configuration of these alarms and the system configuration is also possible. The human-machine interface can be connected directly to the invention or wirelessly further away from the invention, including an application that runs on a tablet or smartphone.

Additionally, during installation of the invention, it coordinates and sequences the insulation measurements, phase-to-phase resistance, and background sensor data, if applicable, through a direct connection to each of the phases of the power cable in the spooler. Now, during the operation of the pumping equipment, or any floating neutral electrical system, the insulation value can be measured with the energized system by injecting a common-mode signal, either AC or DC, through a floating star center generated from a choke or the star center of the transformer that feeds the electrical grid. This is done in coordination with the downhole sensor, the latter being disconnected during this operation. Recording insulation measurements during installation and operation allows for trends that can predict the occurrence of an insulation failure. Recording phase-by-phase resistance variables allows for calculating the temperature of the downhole equipment by calculating resistances and knowing the geometry of the system. Recording variables during installation and operation allows for determining other variables of interest, such as system polarization and dielectric absorption.

The system allows for determining the resistances of each element by prior measurement of the surface equipment (choke, transformer) and for determining the remaining downhole equipment by calculation. The system detects and generates alarms in the event of any voltage generated by the downhole equipment, which could be a safety concern for personnel during the installation process. The system detects voltages generated during pumping system shutdown, which will cause the downhole pump to rotate forward or reverse in the event of a surge or pipe drain. This should prevent any restart attempt while the pump is in progress, avoiding problems with the integrity of both the pumping system and personnel

1. A continuous insulation measurement system (1) comprising:
one or more high voltage switches or multiplexers (1-a);
one or more insulation measuring or measuring circuits (1-b);
one or more phase-to-phase resistance measuring circuits (1-c);
one or more voltage presence measuring circuits (1-e);
one or more power and battery systems (1-f);
one or more power and charging circuits (1-g);
one or more control circuits (1-h); and
one or more switches (1-i).

2. The continuous insulation measurement system (1) according to claim 1, wherein the system (1) may further comprise one or more sensor measurement or Readout circuits (1-d).

3. The continuous insulation measurement system (1) according to claim 1, wherein the system (1) is connected to the sensor measurement or readout circuit (1-d).

4. The continuous insulation measurement system (1) according to claim 1, wherein the high voltage switch or multiplexer (1-a) is selected from dry-contact relays or solid-state switches.

5. The continuous insulation measurement system (1) according to claim 1, wherein the insulation measurement or megger circuit (1-b) comprises a voltage boost source that delivers voltages from 100 Vdc to 5000 Vdc.

6. The continuous insulation measurement system (1) according to claim 1, wherein the phase to-phase resistance measurement circuit (1-c) comprises a high-resolution analog-to-digital converter.

7. The continuous insulation measurement system (1) according to claim 1, wherein the power supply system (1-f) comprises a battery that can be lithium, acid, among others, with sufficient Ampere-hours to operate the system continuously without the need for external power for as long as convenient.

8. The continuous insulation measurement system (1) according to claim 1, wherein the power and charging circuit (1-g) comprises an isolated switching-type input source with a variable voltage range to withstand mains variations and a continuous voltage output for powering the circuits and charging the battery.

9. The continuous insulation measurement system (1) according to claim 1, wherein the control circuit (1-h) comprises communication ports, analog and digital inputs and analog and digital outputs, and a set of alarms that allow the coordination and interpretation of the operation of each of the circuits (1-b), (1-c), (1-d), and (1-e).

10. A continuous measurement circuit for de-energized equipment operation (IRH) (2) comprising:
the continuous insulation measurement system (1) according to claims 1 to 9;
one or more mounting frames (2-a);
one or more high-voltage connection conductors (2-b);
one or more wireless interfaces (2-c);
one or more audible alarms (2-d);
one or more light alarms (2-e);
one or more touchscreen displays or HMIs (2-f);
one or more external box control circuits and wireless communication ports (2-g);
and one or more protective boxes or chassis for the measurement system (2-h) 11. A continuous measurement circuit for energized equipment operation (IMO) comprising:
the continuous insulation measurement system (1) according to claims 1 to 9;
one or more switches (1-i);
one or more wireless interfaces (2-c);
one or more choke units or neutral reactors (3-a);
one or more choke star centers (3-b); and
one or more step-up transformer star centers (3-c).
